(19) United States
(12) Patent Application Publication
(10) Pub. No.: US 2007/0232011 A1
(43) Pub. Date: Oct. 4, 2007

(54) Method of forming an active semiconductor device over a passive device and semiconductor component thereof

(75) Inventors: Bishnu P. Gogoi, Scottsdale, AZ (US); Richard J. De Souza, Tempe, AZ (US); Xiaowei Ren, Phoenix, AZ (US)

Correspondence Address: George C. Chen;Bryan Cave LLP, Suite 2200, Two North Central Avenue, Phoenix, AZ, 85004-4406, US

(73) Assignee: Freescale Semiconductor, Inc., Austin, TX (US)

(21) Appl. No.: 11/395,839

(22) Filed: Mar. 31, 2006

(51) Int. Cl. H01L 21/20

(52) U.S. Cl. 438/381

(57) ABSTRACT

A method of forming a semiconductor component (100) having an active semiconductor device (680) above a passive device (470) includes providing a semiconductor wafer (110) having an upper surface (115), forming a trench (216) in the upper surface of the semiconductor wafer, forming a cavity (317) in the semiconductor wafer below the trench, forming the passive device in the cavity; and forming at least a portion of the active semiconductor device in the semiconductor wafer and above the passive device.

### FIELD OF THE INVENTION

This invention relates generally to semiconductor components, and relates more particularly to the formation of active semiconductor devices over passive devices.

### BACKGROUND OF THE INVENTION

High quality, high value passive devices are required in integrated circuit designs for a variety of purposes. As an example, these passive devices can include capacitors. Typically, the layers of material that are formed over a semiconductor wafer to create portions of complimentary metal oxide semiconductor (CMOS) transistors, bipolar transistors, and/or other active semiconductor devices are also used to create the passive devices. Examples of such active device layer-based passive devices include MOS capacitors and polysilicon-polysilicon (poly-poly) capacitors. However, because these passive devices are formed simultaneously with the transistors, these passive devices consume a substantial amount of surface area across a semiconductor wafer, which makes the semiconductor chips larger.

In an attempt to reduce the amount of surface area required for the passive devices, passive devices have been built above the active device circuitry, but these passive devices may be of lower quality.

Accordingly, a need still exists for a method of forming a passive device in connection with an active semiconductor device, where the passive device requires less surface area than in conventional methods such that the size of semiconductor chips can be reduced.

### BRIEF DESCRIPTION OF THE DRAWINGS

The invention will be better understood from a reading of the following detailed description, taken in conjunction with the accompanying figures in the drawings in which:

FIG. 1 illustrates a cross-sectional view of a semiconductor component after a first stage of a manufacturing process according to an embodiment of the invention;

FIG. 2 illustrates a cross-sectional view of the semiconductor component of FIG. 1 after a later stage of the manufacturing process according to an embodiment of the invention;

FIG. 3 illustrates a cross-sectional view of the semiconductor component of FIG. 2 after a subsequent stage of the manufacturing process according to an embodiment of the invention;

FIG. 4 illustrates a cross-sectional view of the semiconductor component of FIG. 3 after a further stage of the manufacturing process according to an embodiment of the invention;

FIG. 5 illustrates a cross-sectional view of the semiconductor component of FIG. 4 after an even later stage of the manufacturing process according to an embodiment of the invention;

FIG. 6 illustrates a cross-sectional view of the semiconductor component of FIG. 5 after a subsequent stage of the manufacturing process according to an embodiment of the invention; and

FIG. 7 illustrates a flow chart for a method of manufacturing a semiconductor component according to an embodiment of the invention.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus. The term “coupled,” as used herein, is defined as directly or indirectly connected in an electrical or non-electrical manner.

### DETAILED DESCRIPTION OF THE DRAWINGS

In an embodiment of the invention, a semiconductor component includes: (a) a semiconductor chip having an upper surface, a trench extending from the upper surface into the semiconductor wafer, and a cavity coupled to the trench, wherein the cavity is wider than the trench and is further away from the upper surface than the trench; (b) a passive device in the cavity; and (c) at least a portion of an active semiconductor device in the semiconductor chip and above the passive device. In another embodiment of the invention, the semiconductor component is formed using the following steps: (a) providing a semiconductor wafer having an upper surface; (b) forming a trench in the upper surface of the semiconductor wafer such that the trench extends a first depth into the semiconductor wafer from the upper surface; (c) forming a cavity in the semiconductor wafer below the trench such that the cavity is wider than the trench and at least a portion of the cavity is in the semiconductor wafer below the first depth; (d) forming a passive device in the cavity; and (e) forming at least a portion of an active semiconductor device in the semiconductor wafer and above the passive device.

As a more detailed example of this manufacturing embodiment, a reaction ion etch can be used to form a slit trench into an upper surface of a semiconductor-on-insulator (SOI) wafer having an electrical insulator layer located between two silicon layers. The slit trench occupies little lateral surface area across the upper surface of the SOI wafer compared to other typical trenches, and the slit trench extends through the first silicon layer, through the electrical insulator layer, and exposes the second silicon layer. Subsequently, an isotropic etch can be used to form a cavity below the slit trench and in the second silicon layer. The cavity is wider than the slit trench and can have a cylindrical cross-section for a bulk silicon substrate or a semi-circular cross-section for a SOI substrate. A passive device such as a capacitor can be formed in the cavity by depositing and/or growing electrically conductive and electrical insulator layers in the cavity. Then, active semiconductor devices such as field effect transistors and/or bipolar transistors can be formed in the first silicon layer, above the lateral cavity, and above the passive device.

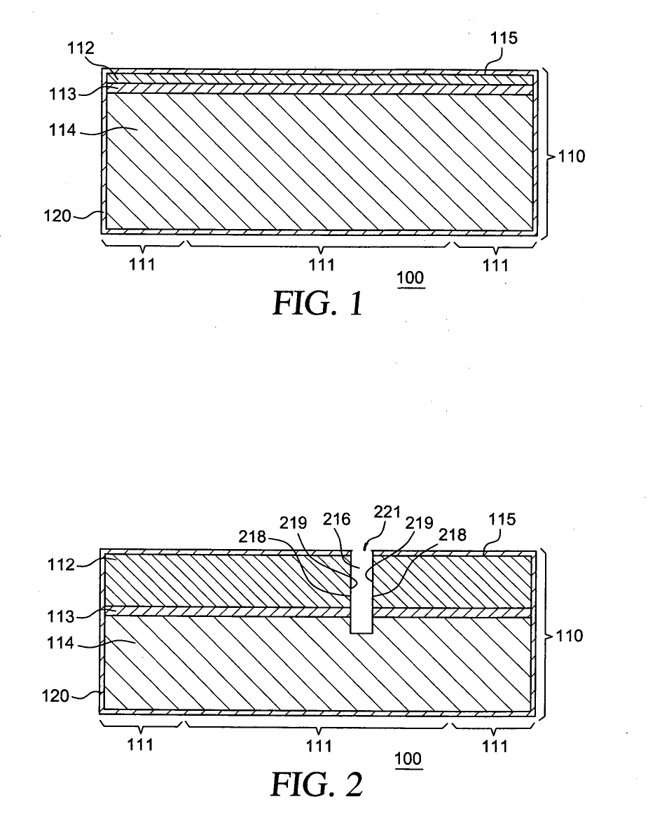

Referring now to the figures, FIG. 1 illustrates a cross-sectional view of a semiconductor component 100 after a first stage of a manufacturing process. As an example, semiconductor component 100 can include a semiconductor wafer 110, which can be subsequently diced or cut into semiconductor die or semiconductor chips 111. In one embodiment, semiconductor wafer 110 can be a semiconductor-on-insulator (SOI) wafer or substrate having a silicon layer 112, a silicon layer 114, and an electrical insulator layer 113 located between silicon layers 112 and 114. In a different embodiment, semiconductor wafer 110 can be a bulk silicon wafer or substrate.

As an example, silicon layer 114 can be doped to be electrically conductive and can be called a handle wafer. Silicon layer 112 can be an active silicon layer. In one embodiment, silicon layer 112 can be epitaxially grown. Silicon layer 112 forms an upper surface 115 for semiconductor wafer 110. In a different embodiment, silicon layer 112 can be replaced with a different semiconductor material such as silicon-germanium, germanium, gallium arsenide, or the like. Similarly, silicon layer 114 can also be replaced with a different semiconductor or non-semiconductor material. Electrical insulator layer 113 can be comprised of silicon oxide and, in some embodiments, can be called a buried oxide (BOX) layer. In a different embodiment, electrical insulator layer 113 can comprise other electrical insulator materials such as silicon nitride, silicon oxy-nitride, or the like. As an example, the combined thickness of silicon layer 112 and electrical insulator layer 113 can be less than 0.5 micrometers. In another embodiment semiconductor wafer 110 is a relatively homogenous semiconductor substrate that does not include an electrical insulator layer. As an example, semiconductor wafer 110 can comprise a p-type bulk silicon wafer or an n-type bulk silicon wafer.

In addition to semiconductor wafer 110, semiconductor component 100 also includes a masking layer 120. As illustrated in FIG. 1, masking layer 120 can encapsulate semiconductor wafer 110. In a different embodiment, masking layer 120 can cover top surface 115, but not other surfaces of semiconductor wafer 110. Masking layer 120 can comprise materials such as photoresist, silicon oxide, silicon nitride, silicon oxy-nitride, and the like.

Turning to the next drawing, FIG. 2 illustrates a cross-sectional view of semiconductor component 100 after a later stage of the manufacturing process. Masking layer 120 is patterned to create a hole 221 in masking layer 120. Masking layer 120 is used to define an opening in upper surface 115 of semiconductor wafer 110. In a different embodiment, many holes similar to hole 221 are formed in masking layer 120.

After forming hole 221 in masking layer 120, a trench 216 is formed in semiconductor wafer 110. Trench 216 extends a depth into semiconductor wafer 110 from upper surface 115. As illustrated in FIG. 2, trench 216 extends through silicon layer 112, extends through electrical insulator layer 113, and exposes silicon layer 114. Trench 216 can also be formed partially into silicon layer 114. As explained below, trench 216 is located at a region of surface 115 where an active semiconductor device will be subsequently formed.

In one embodiment, a deep reactive ion etch (DRIE) process can be used to form trench 216 through silicon layer 112 and through the electrical insulator layer 113. The DRIE process can produce a polymer that coats, passivates, or protects a sidewall 218 of trench 216. As an example, a first portion of a substantially anisotropic etch process can be used to form trench 216 through silicon layer 112 and to form a first portion of a passivation layer 219 over sidewall 218 of trench 216. Then, a second .portion of the substantially anisotropic etch process can be used to form trench 216 through electrical insulator layer 113 and to form a second portion of passivation layer 219 over sidewall 218 of trench 216 and over the first portion of passivation layer 219. The first and second portions of passivation layer 219 can comprise different materials, or they can comprise similar or the same materials. In one embodiment, a portion of passivation layer 219 is formed in sidewall 218. Passivation layer 219 is not formed over the bottom surface of trench 216.

As an example, when semiconductor wafer 110 is a SOI wafer as illustrated in FIG. 2, trench 216 can have a depth of approximately 0.5 micrometers into semiconductor wafer 110 from upper surface 115. As another example, when semiconductor wafer 110 is a p-type or n-type silicon wafer, trench 216 can have a depth of approximately 10.0 micrometers into semiconductor wafer 110 from upper surface 115. Regardless of the type of material used for semiconductor wafer 110, the depth of trench 216 is preferably larger than the depth of subsequently formed n-type and/or p-type wells used to for the active semiconductor devices. In one embodiment, trench 216 can have a width of approximately 0.5 to 1.0 micrometers.

In a different embodiment when semiconductor wafer 110 is a bulk silicon wafer, trench 216 extends below the subsequently formed active area of semiconductor devices. As an example, in this embodiment, trench 216 can extend approximately ten micrometers into semiconductor wafer 110, which can be deeper than when semiconductor wafer 110 is a SOI wafer. Also in this different embodiment, the DRIE process can be broken down into several parts or stages to form trench 216. As an example, the DRIE process can be used to form a portion of trench 216 that is 0.5 micrometers deep. Then, a polymer or passivation layer can be formed on sidewall 218 and/or over any polymer or passivation layers that were previously formed over sidewall 218 during the DRIE process. Next, the DRIE process can be continued to form another portion of trench 216 or to extend the depth of trench 216 into semiconductor wafer 110 by an additional 0.5 micrometers. These steps can be repeated until a desired depth of approximately ten micrometers is reached.

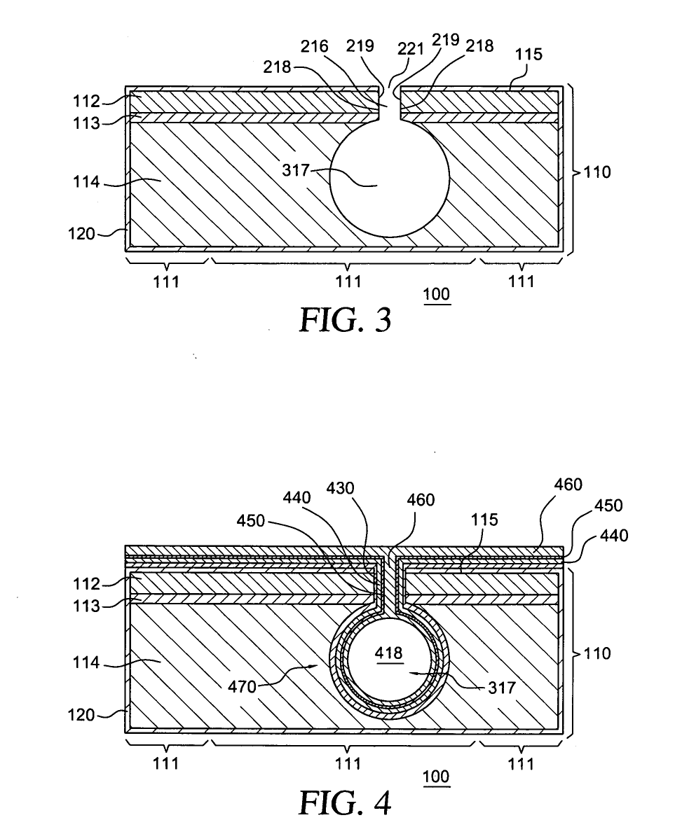

FIG. 3 illustrates a cross-sectional view of semiconductor component 100 after a subsequent stage of the manufacturing process. After forming trench 216, a cavity 317 is formed in semiconductor wafer 110 below and coupled to trench 216. Cavity 317 is wider than trench 216. In one embodiment, cavity 317 is at least two times wider than trench 216. At least a portion of cavity 317 is located in silicon layer 114. Cavity 317 is further away from upper surface 115 than trench 216.

In one embodiment, a substantially isotropic etch process can be used to form cavity 317 in semiconductor wafer 110. As an example, xenon difluoride can be used as the isotropic etchant for silicon layer 114. In this example, the bottom surface of trench 216 is exposed to the xenon difluoride, which etches silicon layer 114. Passivation layer 219 is used during the formation of cavity 317 to protect sidewalls 218 of trench 216 from the etchant by inhibiting the substantially isotropic etchant from etching sidewalls 218. In this manner, the isotropic etchant can be highly selective to insulation or passivation layers.

Furthermore, in the same or a different embodiment, cavity 317 can have a substantially cylindrical cross-section. In this embodiment, the circumference of the cylinder determines the surface area of the passive device. In the same or a different embodiment, cavity 317 can be formed only after the formation of trench 216. Cavity 317 can also have other shapes. Passivation layer 219 protects sidewall 218 of trench 216 during the formation of cavity 317, and masking layer 120 can be used to protect surface 115 and other external surfaces of semiconductor wafer 110 during that same step. In a different embodiment, masking layer 120 can be removed after forming trench 216, and a different masking layer can be used to protect surface 115 and the other external surfaces of semiconductor wafer 110.

FIG. 4 illustrates a cross-sectional view of semiconductor component 100 after a further stage of the manufacturing process. A passive device 470 is formed in cavity 317. In the embodiment illustrated in FIG. 4, passive device 470 is a capacitor. Passive device 470 is located below upper surface 115 and below the remaining part of trench 216 (FIG. 3) in cavity 317. When cavity 317 has a cylindrical cross-section, passive device 470 also has a cylindrical cross-section. In one embodiment, passive device 470 is also located in trench 216 (FIG. 2).

Passive device 470 can comprise four layers, namely, layers 430, 440, 450, and 460. In a different embodiment, passive device 470 can comprise a portion of silicon layer 114, layer 430, and layer 440. In this different embodiment, passivation device 470 can be a shunt capacitor, and layers 450 and 460 are not used in semiconductor component 100.

As an example, layer 430 can be formed over a surface or sidewall of cavity 317, over sidewall 218 of trench 216, and over upper surface 115 of semiconductor wafer 110. In one embodiment, a portion of layer 430 is formed in silicon layer 114. Layer 430 can be an electrical insulator layer and can be formed by growing a thermal oxide, depositing an oxide, silicon nitride, silicon oxy-nitride, tertraethylorthosilicate (TEOS), or the like, or growing and/or depositing a combination dielectric comprised of any of the previously listed materials. In an embodiment where passive device 470 is formed after previously forming active semiconductor devices with gate oxides, layer 430 is preferably not formed using a thermal oxidation growth process to preserve the previously formed gate oxides. In a different embodiment, layer 430 can comprise one or more high-k dielectric materials. The thickness of layer 430 is dependent upon the application for the capacitor in which layer 430 is used. When layers 450 and 460 are used in semiconductor component 100, layer 430 can be called an isolation layer.

Layer 440 can be formed over layer 430, in cavity 317, in trench 216 (FIG. 2), and over upper surface 115 of semiconductor wafer 110. In one embodiment, layer 440 is an electrically conductive layer. As an example, layer 440 can comprise a layer of in-situ doped polysilicon to provide a more uniform doping profile within layer 440. To conformally coat layer 430, layer 440 can be deposited using a low pressure chemical vapor deposition (LPCVD) process. In a different embodiment, layer 440 can be a metal, a metal silicide, a metal anitimonide, a metal boride, or the like. Layer 440 can have a thickness of approximately 0.1 to 0.5 micrometers.

Layer 450 can be formed over layer 440, in cavity 317, in trench 216 (FIG. 2), and over upper surface 115 of semiconductor wafer 110. In one embodiment, layer 450 is an electrically insulating layer. As an example, layer 450 can be similar to layer 430. In an embodiment of passive device 470 having layers 450 and 460, layer 440 is preferably a polysilicon layer so that layer 450 can be more easily formed using a thermal oxidation growth process.

Layer 460 can be formed over layer 450, in cavity 317, in trench 216 (FIG. 2), and over upper surface 115 of semiconductor wafer 110. In one embodiment, layer 460 is an electrically conductive layer. As an example, layer 460 can be similar to layer 440.

When layers 450 and 460 are not used in semiconductor component 100, the thickness of layer 440 is chosen to be large enough to seal trench 216 (FIG. 2). Similarly, when layer 460 is used in semiconductor component 100, the thickness of layer 460 is chosen to be large enough to seal trench 216 (FIG. 2), as illustrated in FIG. 4. After trench 216 is sealed, a portion of cavity 317 remains unfilled with a solid material. Consequently, a void 418 is formed, created, or sealed in cavity 317 in semiconductor wafer 110, along with passive device 470. Void 418 can be filled with a gas or can be a vacuum.

When layers 450 and 460 are not used in semiconductor component 100, a portion of layer 440 is used as a first electrode for the shunt capacitor or passive device 470, and a portion of silicon layer 114 is used as a second electrode for the shunt capacitor or passive device 470. When layers 450 and 460 are used in semiconductor component 100, a portion of layer 440 is used as a first electrode for the capacitor or passive device 470, and a portion of layer 460 is used as a second electrode for the capacitor or passive device 470.

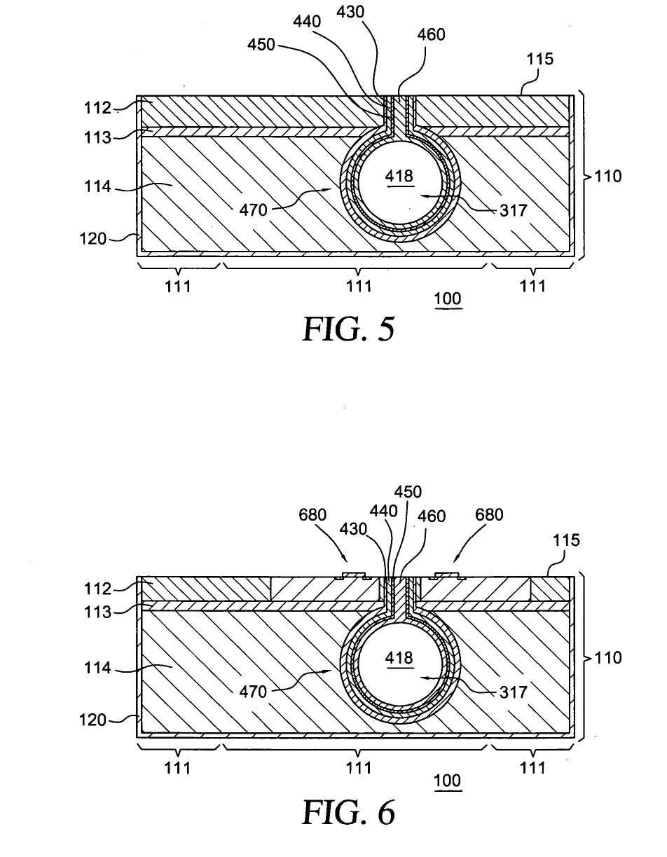

FIG. 5 illustrates a cross-sectional view of semiconductor component 100 after an even later stage of the manufacturing process. After the formation of layers 430, 440, 450, and 460, the portion of layers 430, 440, 450, and 460 that are located over upper surface 115 are removed. As an example, the removal can be accomplished by using an etching process and/or a polishing process. In one embodiment, the polishing process is a chemical mechanical polish (CMP). At least the portion of masking layer 120 located over upper surface 115 is also removed. In a different embodiment, at least the portion of masking layer 120 located over upper surface 115 can be removed before forming passive device 470 in FIG. 4.

FIG. 6 illustrates a cross-sectional view of semiconductor component 100 after a subsequent stage of the manufacturing process. One or more active semiconductor devices 680 are formed in semiconductor wafer 110. Active semiconductor devices 680 and passive device 470 can be part of an integrated circuit. In a different embodiment, two passive devices can be formed on opposite sides of one active semiconductor device. In this different embodiment, the active semiconductor device can be a power and/or high frequency transistor, and the two passive devices can be input and output matching capacitors for the transistor.

As an example, active semiconductor devices 680 can be formed in silicon layer 112. In a different embodiment, active semiconductor devices 680 can be formed in a different semiconductor layer formed over silicon layer 112 after the formation of passive device 470. In this different embodiment, active semiconductor devices 680 can be formed in both the different semiconductor layer and silicon layer 112, and the different semiconductor layer can be considered part of semiconductor wafer 110.

At least a portion of one of active semiconductor devices 680 is located above passive device 470. In this manner, the same vertical area of semiconductor wafer 110 can be used to form active semiconductor devices 680 and passive device 470, which can conserve surface area across upper surface 115 of semiconductor wafer 110 and which can result in smaller semiconductor chips 111. In computer simulated comparisons, a ratio of the surface area that a typical lateral or planar capacitor consumes across upper surface 115 of semiconductor wafer 110 compared to the surface area that passive device 470 consumes across the same surface has been calculated to be 31:1 and even as high as 44:1. As illustrated in FIG. 6, active semiconductor devices 680 do not have to be located exactly or directly over passive device 470.

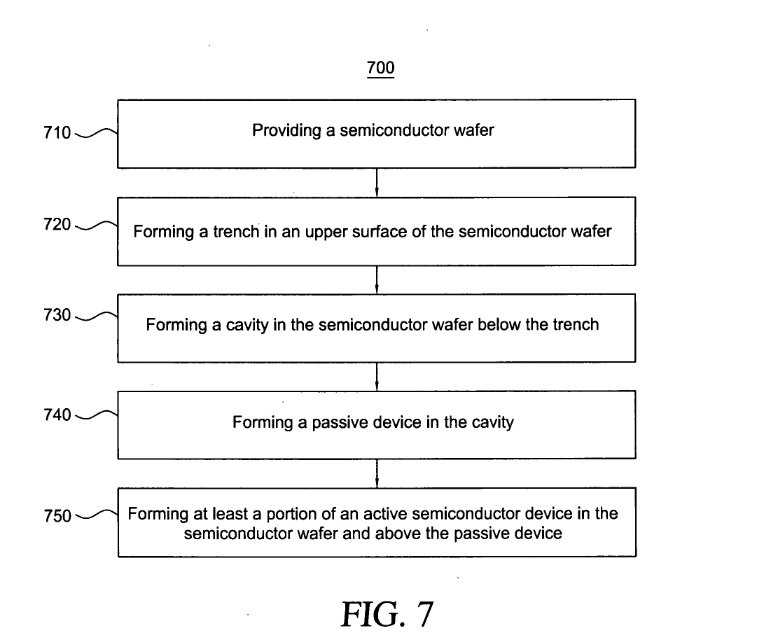

Active semiconductor devices 680 can be field effect transistors such as CMOS transistors, bipolar transistors, and/or diodes. In one embodiment, active semiconductor devices 680 can be formed after all of passive device 470 is formed, including its electrodes or electrical contacts. In a different embodiment, the intrinsic portion of passive device 470 is formed before forming active semiconductor devices 680, and the electrodes or electrical contacts of passive device 470 and active semiconductor devices 680 can subsequently be formed at the same time. FIG. 7 illustrates a flow chart 700 for a method of manufacturing a semiconductor component. The manufacturing method forms an active semiconductor device above a passive device. Flow chart 700 includes a step 710 for providing a semiconductor wafer. As an example, the semiconductor wafer of step 710 can be similar to semiconductor wafer 110 in FIG. 1. Flow chart 700 in FIG. 7 continues with a step 720 for forming a trench in an upper surface of the semiconductor wafer. As an example, the trench of step 720 can be similar to trench 216 in FIG. 2. Next, flow chart 700 in FIG. 7 proceeds with a step 730 for forming a cavity in the semiconductor wafer below the trench. As an example, the cavity of step 730 can be similar to cavity 317 in FIG. 3.

Subsequently, flow chart 700 in FIG. 7 continues with a step 740 for forming a passive device in the cavity. As an example, the passive device in step 740 can be similar to passive device 470 in FIG. 4. Next, flow chart 700 in FIG. 7 proceeds with a step 750 forming at least a portion of an active semiconductor device in the semiconductor wafer and above the passive device. As an example, the active semiconductor device of step 750 can be similar to active semiconductor devices 680 in FIG. 6.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that layers 430, 440, 450, and 460 may be implemented in a variety of embodiments, and that the foregoing discussion of certain of these embodiments does not necessarily represent a complete description of all possible embodiments. As another example, in a different embodiment, the active device(s) can be formed before forming the passive device(s) below the active device(s).

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims. Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A method of forming a semiconductor component having an active semiconductor device above a passive device, the method comprising:
providing a semiconductor wafer having an upper surface;
forming a trench in the upper surface of the semiconductor wafer, wherein the trench extends a first depth into the semiconductor wafer from the upper surface;
forming a cavity in the semiconductor wafer below the trench, wherein the cavity is wider than the trench and at least a portion of the cavity is in the semiconductor wafer below the first depth;
forming the passive device in the cavity; and
forming at least a portion of the active semiconductor device in the semiconductor wafer and above the passive device.

2. The method of claim 1 wherein:
forming the passive device further comprises:
forming a capacitor for the passive device.

3. The method of claim 2 wherein:
forming the capacitor further comprises:
forming a shunt capacitor for the capacitor.

4. The method of claim 1 wherein:
forming the passive device further comprises:
forming a first layer over a surface of the cavity; and
forming a second layer over the first layer and in the cavity.

5. The method of claim 4 wherein:
forming the first layer further comprises:
forming an electrical insulator layer for the first layer; and
forming the second layer further comprises:
forming an electrically conductive layer for the second layer.

6. The method of claim 4 wherein:
forming the second layer further comprises:
forming the second layer to seal the trench and to seal a void in the cavity.

7. The method of claim 6 wherein:
forming the passive device further comprises:
using a portion of the electrically conductive layer as a first electrode for the shunt capacitor; and
using a portion of the semiconductor wafer as a second electrode for the shunt capacitor.

8. The method of claim 5 further comprising:
forming a second electrical insulator layer over the electrically conductive layer; and
forming a second electrically conductive layer over the electrical insulator layer,
wherein:
forming the passive device further comprises:
using a portion of the electrically conductive layer as a first electrode for the capacitor; and
using a portion of the second electrically conductive layer as a second electrode for the capacitor.

9. The method of claim 8 wherein:
forming the second electrically conductive layer further comprises:
using the second electrically conductive layer to seal the trench and to seal a void in the cavity.

10. The method of claim 2 wherein:
forming the cavity further comprises:
forming the cavity to have a substantially cylindrical cross-section; and
forming the capacitor further comprises:
forming the capacitor in the cavity to have a substantially cylindrical cross section.

11. The method of claim 1 wherein:
providing the semiconductor wafer further comprises:
providing a SOI wafer for the semiconductor wafer, wherein the SOI wafer comprises a first semiconductor layer forming the upper surface of the semiconductor wafer, a second semiconductor layer, and an electrical insulator layer between the first and second semiconductor layers;
forming the trench further comprises:
using a substantially anisotropic etch process to form the trench through the first semiconductor layer and through the electrical insulator layer;
forming the cavity further comprises:
after forming the trench, using a substantially isotropic etch process to form the cavity in the second semiconductor layer;
forming the passive device further comprises:
forming a capacitor for the passive device; and
forming at least the portion of the active semiconductor device further comprises:
after forming the passive device, forming a transistor for the active semiconductor device.

12. The method of claim 1 wherein:
providing the semiconductor wafer further comprises:
providing a SOI wafer for the semiconductor wafer, wherein the SOI wafer has a first semiconductor layer forming the upper surface of the semiconductor wafer, a second semiconductor layer, and an electrical insulator layer between the first and second semiconductor layers;
forming the trench further comprises:
using a first portion of a substantially anisotropic etch process to form the trench through the semiconductor layer;
forming a first portion of a passivation layer over a sidewall of the trench;
using a second portion of the substantially anisotropic etch process to form the trench through the electrical insulator layer;
forming a second portion of the passivation layer over the sidewall of the trench and the first portion of the passivation layer; and
forming the cavity further comprises:
using a substantially isotropic etch process to form the cavity in the second semiconductor layer; and
using the passivation layer to inhibit etching of the sidewall of the trench while using the substantially isotropic etch process to form the cavity.

13. The method of claim 1 wherein:
forming the trench further comprises:
using a substantially anisotropic etch process to form the trench.

14. The method of claim 14 wherein:
forming the cavity further comprises:
using a substantially isotropic etch process to form the cavity.

15. The method of claim 14 wherein:
forming the trench further comprises:
forming a passivation layer over a sidewall of the trench while forming the trench.

16. A semiconductor component having an active semiconductor device above a passive device comprising:
a semiconductor chip comprising an upper surface, a trench extending from the upper surface into the semiconductor chip, and a cavity coupled to the trench, wherein the cavity is wider than the trench and is further away from the upper surface than the trench;
the passive device in the cavity; and
at least a portion of the active semiconductor device in the semiconductor chip and above the passive device.

17. The semiconductor component of claim 13 wherein:
the passive device is a capacitor.

18. The semiconductor component of claim 13 wherein:
a void is located in the cavity with the capacitor.

19. The semiconductor component of claim 13 wherein:
the active semiconductor device is a transistor.

20. A semiconductor component having an active semiconductor device above a passive device comprising:
a SOI chip comprising:
a first semiconductor layer forming an upper surface of the SOI chip;
a second semiconductor layer doped to be electrically conductive; and
an electrical insulator layer between the first and second semiconductor layers,
wherein:
a trench extends through the first semiconductor layer and through electrical insulator layer; and
a cavity is located in the second semiconductor layer, is coupled to the trench, and is wider than the trench;
the passive device in the cavity; and
at least a portion of the active semiconductor device in the first semiconductor layer and above the passive device.
